(19) United States
(12) Patent Application Publication
(10) Pub. No.: US 2012/0264284 A1
(43) Pub. Date: Oct. 18, 2012

(54) MANUFACTURING METHOD FOR METAL GATE STRUCTURE

(76) Inventors: Shao-Wei Wang, Taichung City (TW); Ying-Wei Yen, Miaoli County (TW); Yu-Ren Wang, Tainan City (TW); Chien-Liang Lin, Taoyuan County (TW)

(21) Appl. No.: 13/086,410

(22) Filed: Apr. 14, 2011

(51) Int. Cl. H01L 21/28

(52) U.S. Cl. 438/592; 257/E21.19

(57) ABSTRACT

A manufacturing method for a metal gate structure includes providing a substrate having a gate trench formed thereon, forming a work function metal layer in the gate trench, and performing an annealing process to the work function metal layer. The annealing process is performed at a temperature between 400° C. and 500° C., and in a bout 20 seconds to about 180 seconds.

### BACKGROUND OF THE INVENTION

1. Field of the Invention

The invention relates to a manufacturing method for a metal gate structure, and more particularly, to a manufacturing method for a p-type metal gate structure.

2. Description of the Prior Art

As the dimensions of transistors decrease, the thickness of the gate dielectric layer must be reduced to maintain performance with the decreased gate length. In order to reduce gate leakage, high dielectric constant (high-K) gate dielectric layers which allow greater physical thickness while maintaining the same effective thickness as would be provided by the conventional oxide are used to replace the conventional oxide layers. Furthermore, the high-K gate dielectric layers obtain equivalent capacitor in an identical equivalent oxide thickness (EOT).

Also, as technology node shrink, there has been developed to replace the typical polysilicon gate with a metal gate to improve device performance with the decreased feature sizes. By introducing metal gates, the threshold voltage of the metal oxide semiconductor (MOS) transistor becomes controlled by the metal work function. Regarding the metal gate, tuning of the work function is required as a different work function is needed for n-channel MOS (NMOS) transistor (i.e. a work function preferably between about 3.9 eV and about 4.3 eV) and for p-channel MOS (PMOS) transistor (i.e. a work function preferably between about 4.8 eV and about 5.2 eV).

In current process for fabricating a p-type metal gate, a Spike annealing process is used to drive oxygen diffusion. Accordingly, the work function of the metal gate structure is moved to the mid band gap of silicon. Therefore, it is possible to use the metal gate structure as a single gate electrode that permits forming symmetrical threshold voltages in the PMOS. However, the prior art using the Spike annealing process for tuning the work function of the p-type metal gate structure always faces problem that the stability of the Spike annealing process is not easy to be controlled and therefore suffers narrow time window. Since the Spike anneal annealing process has the stability issue, it is found that the electrical performances of the p-type metal gate structures are different lot by lot after executing the wafer acceptance test (WAT). That means a lot-by-lot variation undesirably occurs to the electrical performances of the p-type metal gate structure.

Therefore, there is a continuing need in the semiconductor processing art to develop a manufacturing method for a metal gate structure that is able to solve the abovementioned problems.

### SUMMARY OF THE INVENTION

According to an aspect of the present invention, there is provided a manufacturing method for a metal gate structure. The manufacturing method includes providing a substrate having a gate trench formed thereon, forming a work function metal layer in the gate trench, and performing an annealing process to the work function metal layer. The annealing process is performed at a temperature between 400° C. and 500° C. and in about 20 seconds to about 180 seconds.

According to the manufacturing method for a metal gate structure, the annealing process is performed for tuning the work function of the work function metal layer at the temperature between 400° C. and 500° C. More important, the annealing process is performed in about 20 seconds to about 180 seconds. Compared with the prior art, the annealing process provided by the present invention provides much wider time window. Accordingly, result of work function tuning is improved, higher stability is obtained, and thus performance variation is eliminated.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 are schematic drawings illustrating a manufacturing method for a metal gate structure provided by a first preferred embodiment of the present invention.

FIG. 6 is a diagram presenting comparison of post metal annealing results.

FIGS. 7-10 are schematic drawings illustrating a manufacturing method for a metal gate structure provided by a second preferred embodiment of the present invention.

### DETAILED DESCRIPTION

Please refer to FIGS. 1-5, which are schematic drawings illustrating a manufacturing method for a metal gate structure provided by a first preferred embodiment of the present invention. It is noteworthy that the preferred embodiment is integrated with the gate last process. As shown in FIG. 1, a substrate 100 such as silicon substrate, silicon-containing substrate, III/V or II/VI compound semiconductors-containing substrate, silicon-on-insulator (SOI) substrate, SiGe-on-insulator (SGOI) substrate, or germanium-on-insulator (GOI) substrate, is provided. The substrate 100 may include a single crystal orientation or it may include at least two coplanar surface regions having different crystal orientations, such as a (100) crystal surface for the NFET and a (110) crystal surface for the PFET. Moreover, a hybrid substrate having the two regions with different crystal orientations can be formed by techniques that are well known in the art. The substrate 100 includes a plurality of shallow trench isolations (STIs) (not shown) for providing electrical isolation formed therein.

Please refer to FIG. 1 again. A semiconductor device 150 is formed on the substrate 100. The semiconductor device 150 includes a dummy gate 110, lightly-doped drains (LDDs) 120 formed in the substrate 100 at two sides of the dummy gate 110, a spacer 122 formed at sidewalls of the dummy gate 110, and a source/drain 124 formed in the substrate 100 at two sides of the spacer 122. As shown in FIG. 1, the spacer 122 can be a multi-layered structure having an L-shaped seal layer and an insulting layer. It is well-known to those skilled in the art that selective strain scheme (SSS) can be used in the preferred embodiment. For example, a selective epitaxial growth (SEG) method can be used to form the source/drain 124. Since the semiconductor device 150 is a p-type semiconductor device, epitaxial silicon layers with silicon germanium (SiGe) are used to form the p-type source/drain 124. However, epitaxial silicon layers with silicon carbide (SiC) can be used to form the n-type source/drain 124 if the semiconductor device 150 is an n-type semiconductor device. Additionally, silicides (not shown) are formed on the surface of the source/drain 124 for reducing sheet resistance. After forming the silicide, a contact etch stop layer (CESL) 130 and an inter-layer dielectric (ILD) layer 132 covering the semiconductor device 150 are sequentially formed on the substrate 100.

As shown in FIG. 1. The dummy gate 110 includes an interfacial layer 112, a gate dielectric layer 114, a bottom barrier layer 116, a sacrificial layer 118, and a patterned hard mask (not numbered). In other words, the high-K gate dielectric layer 114 is formed between the sacrificial layer 118 and the interfacial layer 112. The bottom barrier layer 116 can include titanium nitride (TiN), but not limited to this. It is noteworthy that the preferred embodiment is integrated with the high-K first process, therefore the gate dielectric layer 114 includes high-K material such as rare earth metal oxide. For example, the high-K gate dielectric layer 114 can include materials selected from the group consisting of hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate, (SrBi₂Ta₂O₉, SBT), lead zirconate titanate (PbZrₓTi₁₋ₓO₃, PZT) and barium strontium titanate (BaₓSr₁₋ₓTiO₃, BST). The sacrificial layer 118 is preferably a polysilicon layer, but not limited to this.

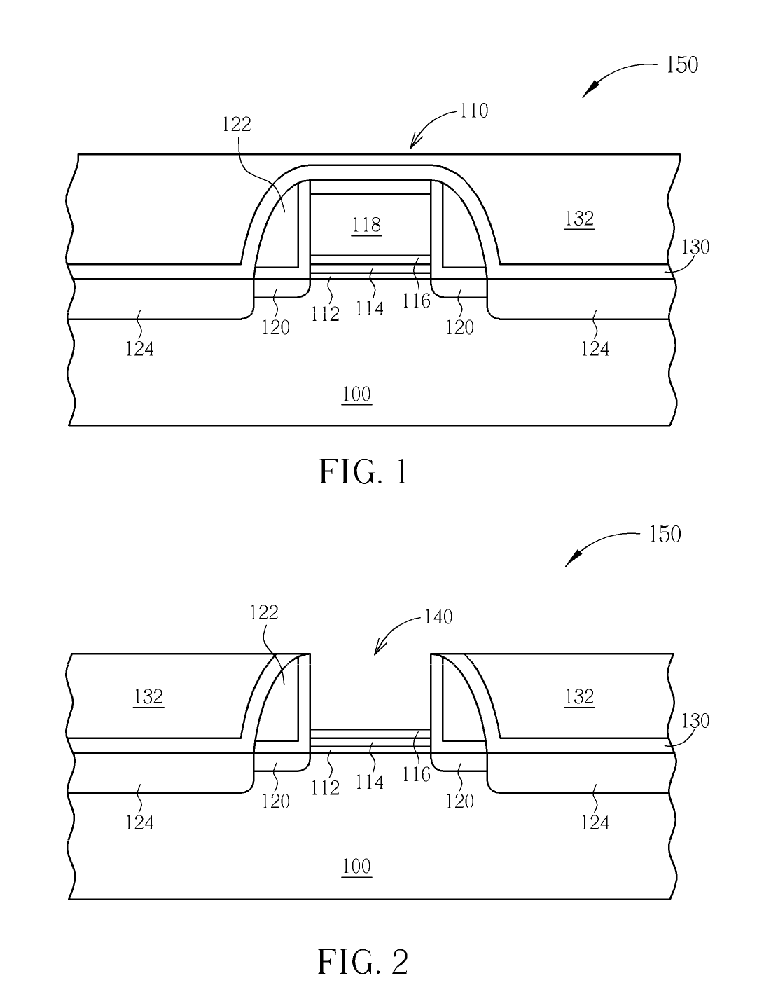

Please refer to FIG. 2. Next, a planarization process is performed to remove a portion of the ILD layer 132, a portion of the CESL 130, and the patterned hard mask. Consequently, the sacrificial layer 118 is exposed. The exposed sacrificial layer 118 is then removed by a proper etching process, and thus a gate trench 140 is formed on the substrate 100. Since the preferred embodiment is integrated with the high-K first process as mentioned above, the high-K gate dielectric layer 114 and the bottom barrier layer 116 are exposed in the bottom of the gate trench 140 after removing the sacrificial layer 118.

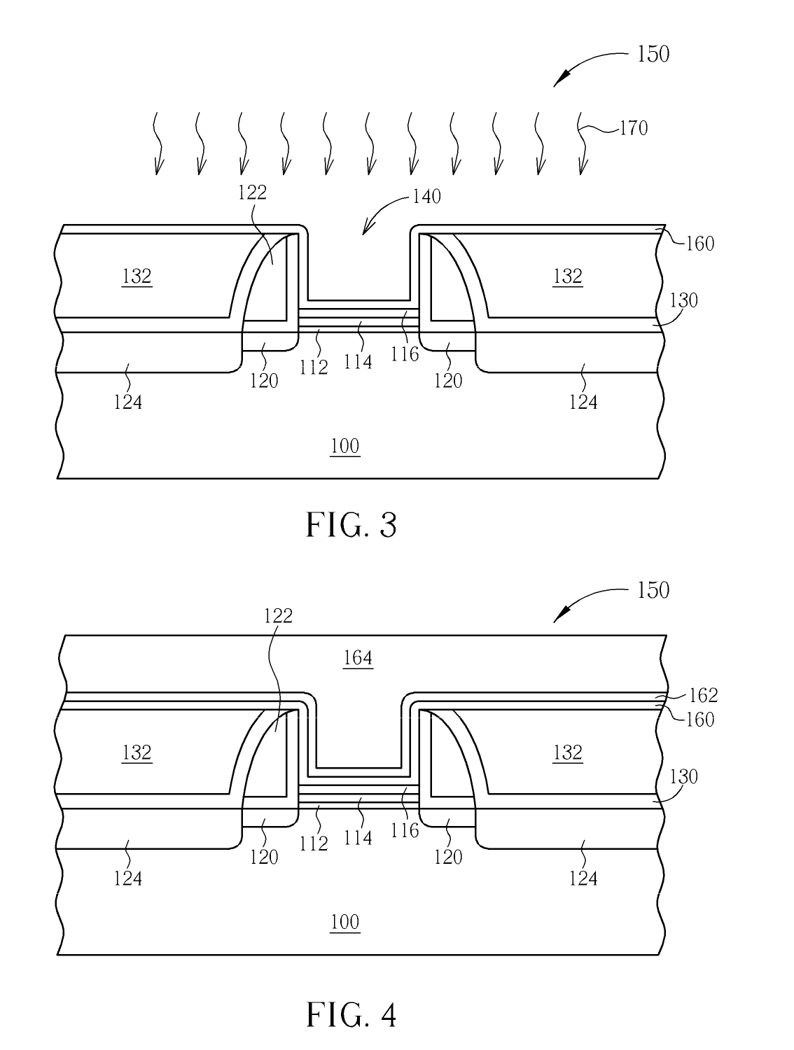

Please refer to FIG. 3. Then, a work function metal layer 160 is formed in the gate trench 140 and on the substrate 100. The work function metal layer 160 includes metal, metal nitride, or metal silicon nitride. After forming the work function metal layer 160, an annealing process 170 is performed to tune a work function of the work function metal layer 160. The annealing process 170 is performed at a temperature between 400° C. and 500° C. and in about 20 seconds to about 180 seconds. The annealing process 170 includes introducing a gas selected from the group consisting of oxygen (O₂), nitrogen (N₂), and ammonia (NH₃). In addition, O₂ gas treatment including O₂ gas, nitrous oxide (N₂O) gas containing O₂ gas, or nitric oxide (NO) gas containing O₂ gas can be introduced to improve the work function of the work function metal layer 160 by diffusing oxygen. The annealing process 170 includes Soak annealing process or a furnace annealing process. In a so-called “Soak” process, the substrate 100 is left at a given process temperature (400° C.-500° C. in this preferred embodiment) for a specified period of time (20-180 seconds in this preferred embodiment) and is then ramped down in temperature for unloading from the process chamber. Different from the conventional Spike annealing process, which increases the temperature of the wafer up to the heat treatment temperature for a short time, and then decreasing the temperature of the wafer without holding the heat treatment temperature, the Soak annealing process 170 provides wider time window. And thus the process stability is improved.

Please refer to FIG. 6, which is a diagram presenting comparison of post-metal annealing results. It is noteworthy that the different post-metal annealing results are obtained by performing the conventional Spike annealing process and the Soak annealing process at different temperature. According to the comparison shown in FIG. 6, it is found that the work function tuning result is improved by the Soak annealing process, compared with the Spike annealing process. Accordingly, the work function of the work function metal layer 160 is between about 4.8 eV and about 5.2 eV after performing the annealing process 170.

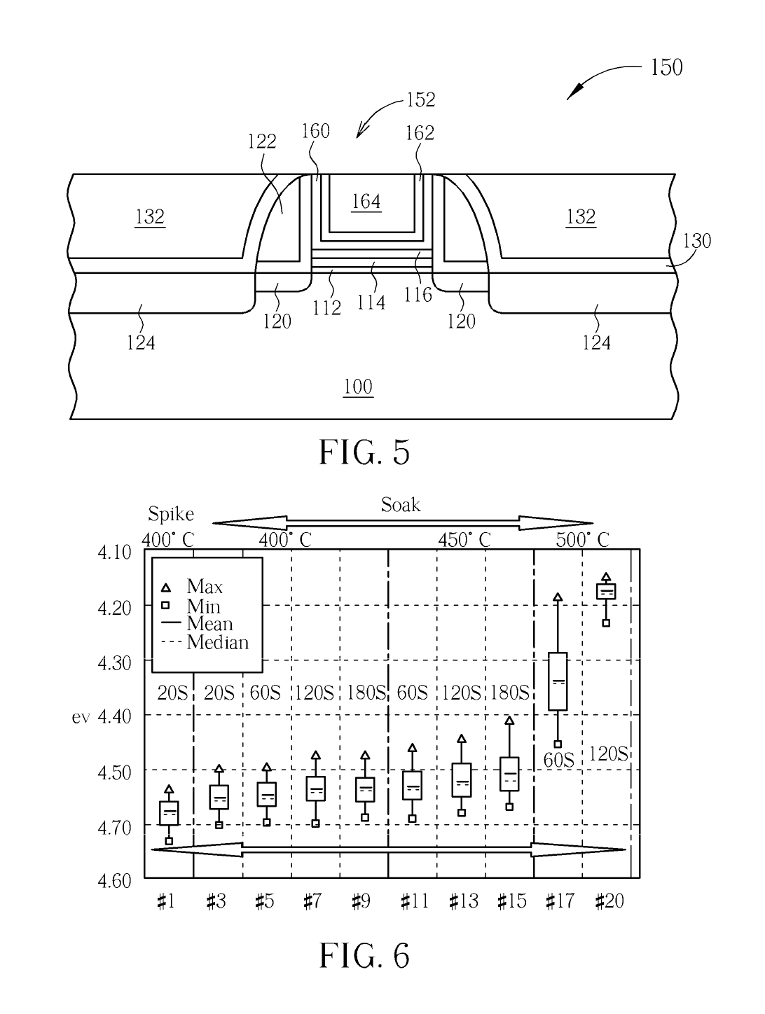

Please refer to FIG. 4 and FIG. 5. After the annealing process 170, a top barrier layer 162 and a filling layer 164 are sequentially formed in the gate trench 140 with the filling layer 164 filling up the gate trench 140. The top barrier layer 162 can include TiN, but not limited to this. The filling layer 164 includes metals or metal oxides having superior gap-filling characteristic and low resistance such as aluminum (Al), titanium aluminide (TiAl), or titanium aluminum oxide (TiAlO), but not limited to this. Please still refer to FIG. 5. Then, a planarization process such as a CMP process is performed to remove unnecessary filling metal layer 164, top barrier layer 162, and work function metal layer 160. Consequently, a metal gate 152 is formed. Furthermore, the ILD layer 132 and the CESL 130 can be selectively removed and sequentially reformed for improving performance of the semiconductor device in the preferred embodiment.

According to the first preferred embodiment, the annealing process 170 is performed for tuning the work function of the work function metal layer 160 at the temperature between 400° C. and 500° C. More important, the annealing process 170 is performed in about 20 seconds to about 180 seconds. Compared with the prior art that requires Spike annealing process, the annealing process 170 of the present invention provides much wider time window. Accordingly, work function tuning result is improved, higher stability is obtained, and thus performance variation is eliminated.

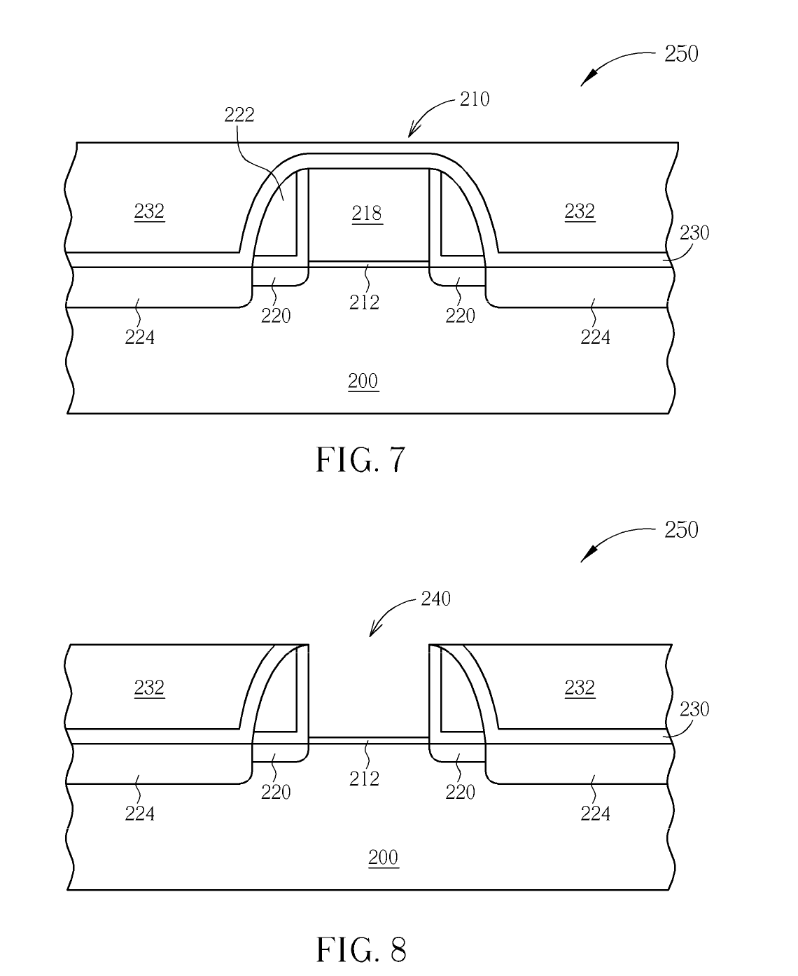

Please refer to FIGS. 7-10, which are schematic drawings illustrating a manufacturing method for a metal gate structure provided by a second preferred embodiment of the present invention. It is noteworthy that the preferred embodiment is also integrated with the gate last process. As shown in FIG. 7, a substrate 200 is provided. The substrate 200 may include materials described in the first preferred embodiment, therefore those details are omitted for simplicity. The substrate 200 includes a plurality of STIs (not shown) for providing electrical isolation formed therein.

Please refer to FIG. 7 again. A semiconductor device 250 is formed on the substrate 200. The semiconductor device 250 includes a dummy gate 210, LDDs 220, a spacer 222, and a source/drain 224. As shown in FIG. 7, the spacer 222 can be a multi-layered structure having an L-shaped seal layer and an insulting layer. As mentioned above, SSS can be used in the preferred embodiment. For example, a SEG method can be used to form the source/drain 224 having SiGe or SiC epitaxial layer. Additionally, silicides (not shown) are formed on the surface of the source/drain 224 for reducing sheet resistance. After forming the silicide, a CESL 230 and an ILD layer 232 covering the semiconductor device 250 are sequentially formed on the substrate 200. The dummy gate 210 includes a gate dielectric layer 212, a sacrificial layer 218, and a patterned hard mask (not numbered). In other words, the gate dielectric layer 212 is formed between the sacrificial layer 218 and the substrate 200. It is noteworthy that the preferred embodiment is integrated with the high-K last process, therefore the gate dielectric layer 212 preferably includes conventional oxide layer. The sacrificial layer 218 is preferably a polysilicon layer, but not limited to this.

Please refer to FIG. 8. Next, a planarization process is performed to remove a portion of the ILD layer 232, a portion of the CESL 230, and the patterned hard mask. Consequently, the sacrificial layer 218 is exposed. The exposed sacrificial layer 218 and a portion of the gate dielectric layer 212 are then removed by a proper etching process, and thus a gate trench 240 is formed on the substrate 200. Since the preferred embodiment is integrated with the high-K last process as mentioned above, the gate dielectric layer 212 can be used to protect the substrate 200 during removing the sacrificial layer 218. Consequently, the gate dielectric layer 212 is exposed in the bottom of the gate trench 240 after removing the sacrificial layer 218.

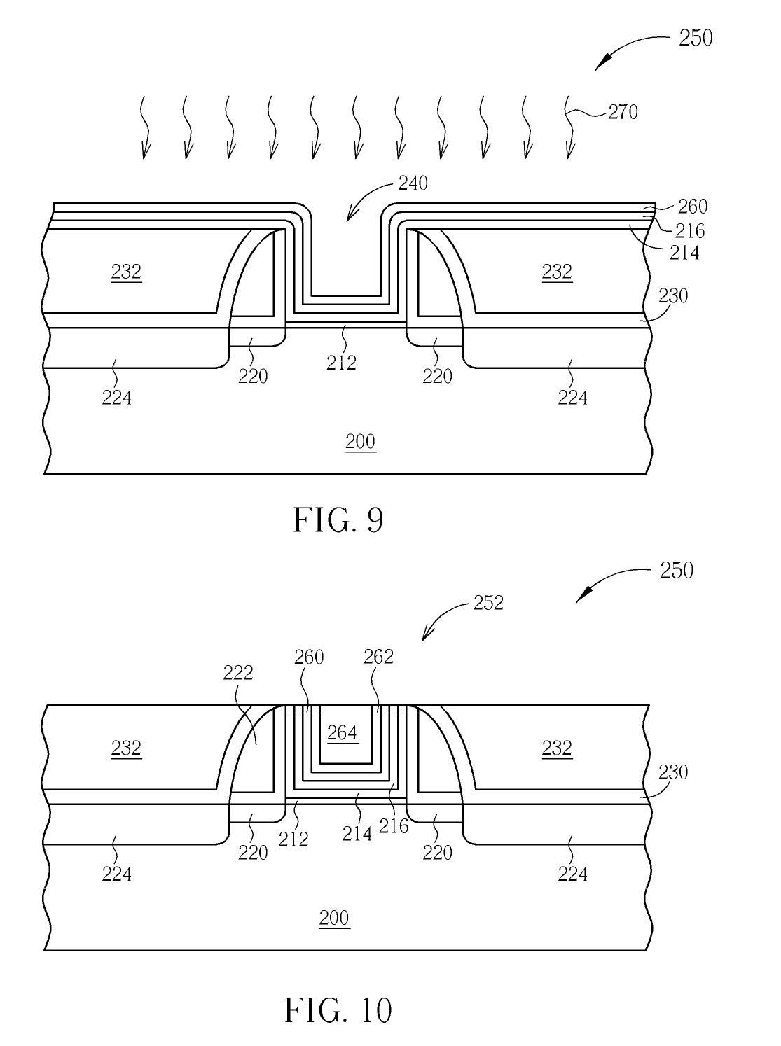

Please refer to FIG. 9. Then, a high-K gate dielectric layer 214, a bottom barrier layer 216, and a work function metal layer 260 are sequentially formed in the gate trench 240 and on the substrate 200. The high-K gate dielectric layer 214 includes high-K material such as rare earth metal oxide. For example, the high-K gate dielectric layer 214 can include materials selected from the group consisting of HfO₂, HfSiO₄, HfSiON, Al₂O₃, La₂O₃, Ta₂O₅, Y₂O_{3, ZrO}₂, SrTiO₃, ZrSiO₄, HfZrO₄, SBT, PZT and BST. The bottom barrier layer 216 can include TiN, but not limited to this. The work function metal layer 260 includes metal, metal nitride, or metal silicon nitride. More important, after forming the work function metal layer 260, an annealing process 270 is performed to tune a work function of the work function metal layer 260. The annealing process 270 is performed at a temperature between 400° C. and 500° C. and in about 20 seconds to about 180 seconds. The annealing process 270 includes introducing a gas selected from the group consisting of O₂, N₂, and NH₃. In addition, O₂ gas treatment including O₂ gas, nitrous oxide (N₂O) gas containing O₂ gas, or nitric oxide (NO) gas containing O₂ gas can be introduced to improve the work function of the work function metal layer 160 by diffusing oxygen. The annealing process 270 includes Soak annealing process or a furnace annealing process. Different from the conventional Spike annealing process, which increases the temperature of the wafer up to the heat treatment temperature for a short time, and then decreasing the temperature of the wafer without holding the heat treatment temperature, the Soak annealing process 270 provides wider time window. And thus the process stability is improved.

Please also refer to FIG. 6. It is noteworthy that the present different post-metal annealing results are also obtained by performing the conventional Spike annealing process and the Soak annealing process at different temperature. According to the comparison shown in FIG. 6, it is found that the work function tuning result is improved by the Soak annealing process 270, compared with the Spike annealing process. Accordingly, the work function of the work function metal layer 260 is between about 4.8 eV and about 5.2 eV after the annealing process 270.

Please refer to FIG. 10. After the annealing process 270, a top barrier layer 262 and a filling layer 264 are sequentially formed in the gate trench 240 with the filling layer 264 filling up the gate trench 240. The top barrier layer 262 can include TiN, but not limited to this. The filling layer 264 includes metals or metal oxides having superior gap-filling characteristic and low resistance such as Al, TiAl, or TiAlO, but not limited to this. Then, a planarization process such as a CMP process is performed to remove unnecessary filling metal layer 264, top barrier layer 262, work function metal layer 260, bottom barrier layer 216, and high-K gate dielectric layer 214. Consequently, a metal gate 252 that is formed on the high-K gate dielectric layer 214 is obtained. Furthermore, the ILD layer 232 and the CESL 230 can be selectively removed and sequentially reformed for improving performance of the semiconductor device in the preferred embodiment.

According to the second preferred embodiment, the annealing process 270 is performed for tuning the work function of the work function metal layer 260 at the temperature between 400° C. and 500° C. More important, the annealing process 270 is performed in about 20 seconds to about 180 seconds. Compared with the prior art that requires Spike annealing process, the annealing process 270 provided by the present invention provides much wider time window. Accordingly, work function tuning result is improved, higher stability is obtained, and thus performance variation is eliminated.

As mentioned above, according to the manufacturing method for a metal gate structure, the annealing process is performed for tuning the work function of the work function metal layer at the temperature between 400° C. and 500° C. More important, the annealing process is performed in about 20 seconds to about 180 seconds. Compared with the prior art, the annealing process provided by the present invention provides much wider time window. Accordingly, result of work function tuning is improved, higher stability is obtained, and thus performance variation is eliminated. Furthermore, the manufacturing method for a metal gate structure provided by the present invention can be performed with the gate last process, it also can be performed with introducing the high-K first process or the high-K last process.

Those skilled in the art will readily observe that numerous modifications and alterations of the device and method may be made while retaining the teachings of the invention.

What is claimed is:

1. A manufacturing method for a metal gate structure comprising:
providing a substrate having a gate trench formed thereon;
forming a work function metal layer in the gate trench; and
performing an annealing process to the work function metal layer, the annealing process being performed at a temperature between 400° C. and 500° C. and in about 20 seconds to about 180 seconds.

2. The manufacturing method for a metal gate structure according to claim 1, further comprising:
forming a dummy gate on the substrate, wherein the dummy gate comprises at least a sacrificial layer; and
removing the sacrificial layer to form the gate trench.

3. The manufacturing method for a metal gate structure according to claim 2, wherein the dummy gate comprises an interfacial layer and a high-K dielectric constant (high-K) gate dielectric layer, and the high-K gate dielectric layer is formed between the sacrificial layer and the interfacial layer.

4. The manufacturing method for a metal gate structure according to claim 3, wherein the high-K gate dielectric layer is exposed in the bottom of the gate trench after removing the sacrificial layer.

5. The manufacturing method for a metal gate structure according to claim 2, wherein the dummy gate further comprises a dielectric layer formed between the sacrificial layer and the substrate.

6. The manufacturing method for a metal gate structure according to claim 5, further comprising:
removing the sacrificial layer and a portion of the dielectric layer to form a gate trench on the substrate;
forming a high-K gate dielectric layer on the dielectric layer in the gate trench; and
forming the metal gate on the high-K dielectric layer in the gate trench.

7. The manufacturing method for a metal gate structure according to claim 1, wherein annealing process comprises a Soak annealing process or a furnace annealing process.

8. The manufacturing method for a metal gate structure according to claim 1, wherein annealing process comprises introducing a gas selected from the group consisting of oxygen (O₂), nitrogen (N₂), and ammonia (NH₃).

9. The manufacturing method for a metal gate structure according to claim 1, wherein a work function of the work function metal layer is between about 4.8 eV and about 5.2 eV after the annealing process.

10. The manufacturing method for a metal gate structure according to claim 1, further comprising forming a bottom barrier layer in the gate trench before forming the work function metal layer.

11. The manufacturing method for a metal gate structure according to claim 1, further comprising:
forming a top barrier layer on the work function metal layer; and
forming a filling metal layer on the top barrier layer.
